(19) United States
(12) Patent Application Publication
(10) Pub. No.: US 2010/0143657 A1
(43) Pub. Date: Jun. 10, 2010

(54) HIGH-TEMPERATURE-DURABLE OPTICAL FILM STRUCTURE AND FABRICATION METHOD THEREOF

(76) Inventors: Shiuh CHAO, Hsinchu (TW); Chen-Yang HUANG, Hsinchu (TW); Hao-Min KU, Hsinchu (TW)

Correspondence Address: Muncy, Geissler, Olds & Lowe, PLLC, 4000 Legato Road, Suite 310, FAIRFAX, VA, 22033, US

(21) Appl. No.: 12/370,316

(22) Filed: Feb. 12, 2009

(30) Foreign Application Priority Data
Dec. 5, 2008 (TW) 97147498

(51) Int. Cl. B32B 3/10; B05D 5/06; G03F 7/00; C23C 14/38; B29D 11/00

(52) U.S. Cl. 428/172; 427/162; 430/321; 204/192.26; 216/24

(57) ABSTRACT

A high-temperature-durable optical film structure and its fabricating method are provided. The optical film structure is formed by covering a surface of a substrate with an optical layer structure and forming a plurality of passage structures on the optical layer structure to divide the optical layer structure into a plurality of optical blocks. The passage structures can be used as a space of releasing the thermal stress to prevent the film deformation and peeling.

### BACKGROUND OF THE INVENTION

1. Field of the Invention

The present invention generally relates to an optical film structure, and more particularly relates to a high-temperature-durable optical film structure.

2. Description of the Prior Art

Thin-film optics has been an important branch of the modern optics, and the fabrication of the optical thin film has become a new emerging industry. At present, various optical thin films are applied to a lot of optical systems and photoelectric systems, and widely used in the people's daily life.

A traditional optical thin film 10 is made of two or more materials using evaporation or sputtering. As shown in FIG. 1, optical thin film 10 includes a substrate 12 and a plurality of planar thin films 14 formed on the substrate 12. When this optical thin film 10 is applied to an optical system operating under high temperature, such as a filter of a solar cell or an optical filter of a mini-projector, the planar thin films 14 may peel off, break or bulge to break the optical filter due to its narrow heat tolerance.

As illustrated in FIG. 2a to FIG. 2c, every thin film 14 of a traditional optical thin film 10 exactly and completely blankets the substrate 12. When the traditional optical thin film 10 are baked at high temperature, such as 1200° C., the deformation and the peeling occurs, as illustrated in FIG. 3a to FIG. 3c.

### SUMMARY OF THE INVENTION

Accordingly, the present invention is directed to a high-temperature-durable optical film structure and a fabrication method thereof. In one embodiment, passage structures are formed on the multi-layer thin film to provide a space for releasing the thermal stress to reduce the possibility of the optical film structure from deforming and peeling at high temperature. An optical film structure using the passage structures may resist high temperature and serve as a high-temperature-durable optical thin film device.

In one embodiment, a high-temperature-durable optical film structure comprises a substrate and an optical layer structure. The optical layer structure is formed on a surface of the substrate and has a plurality of passage structures. The passage structures divide the optical layer structure into a plurality of optical blocks.

In one embodiment, a method for fabricating a high-temperature-durable optical film structure comprises the steps of providing a substrate, forming an optical layer structure on a surface of the substrate and forming a plurality of passage structures on the optical layer structure.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 is a diagram illustrating a traditional optical thin film;

FIG. 2a is a SEM vertical view using low magnifying power to illustrate the traditional optical thin film;

FIG. 2b is a SEM vertical view using high magnifying power to illustrate the traditional optical thin film;

FIG. 2c is a SEM lateral view using high magnifying power to illustrate the traditional optical thin film;

FIG. 3a is a SEM vertical view using low magnifying power to illustrate the traditional optical thin film after baking to 1200° C.;

FIG. 3b is a SEM vertical view using high magnifying power to illustrate the traditional optical thin film after baking to 1200° C.;

FIG. 3c is a SEM lateral view using high magnifying power to illustrate the traditional optical thin film after baking to 1200° C.;

FIG. 4 is a diagram illustrating a high-temperature-durable optical film structure in accordance with an example of the present invention;

FIG. 5a to FIG. 5d are diagrams respectively illustrating a shape and distribution of different optical blocks in accordance with an example of the present invention;

FIG. 6a to FIG. 6e illustrates a flow of a method for fabricating a high-temperature-durable optical film structure in accordance with an example of the present invention;

FIG. 7a and FIG. 7b are respectively a SEM vertical view and a SEM lateral view illustrating a high-temperature-durable optical film structure before baking; and

FIG. 8a and FIG. 8b are respectively a SEM vertical view and a SEM lateral view illustrating the high-temperature-durable optical film structure after baking to 1200° C.

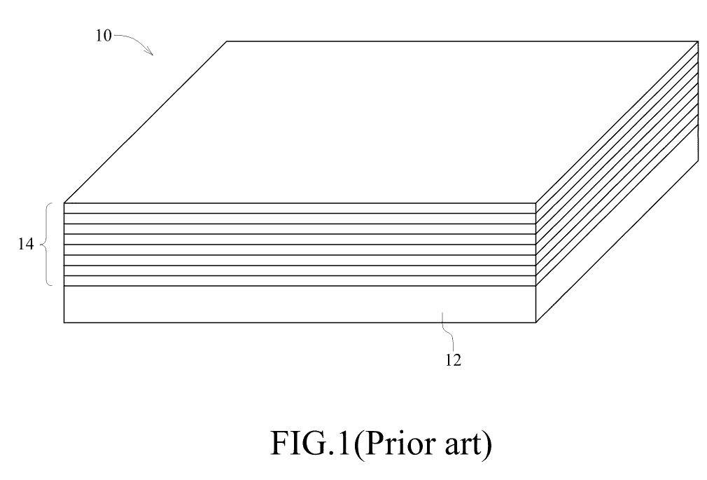

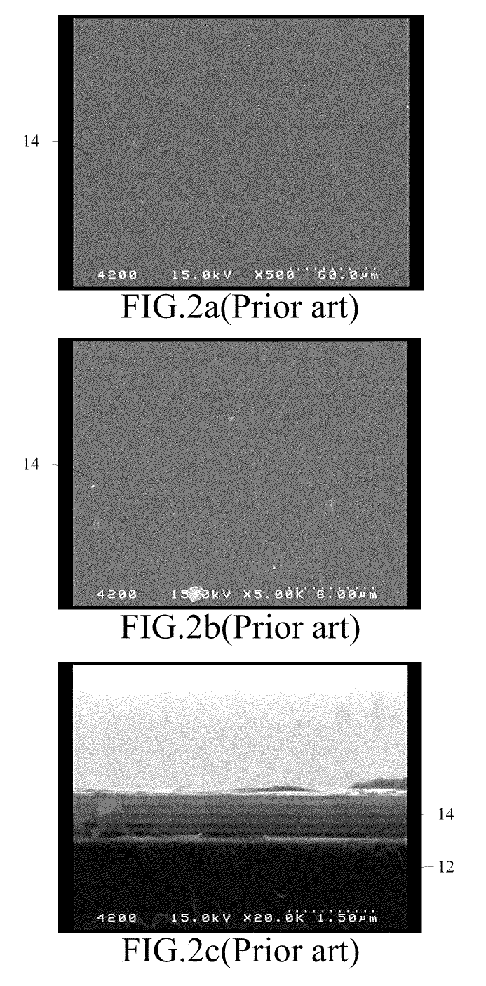

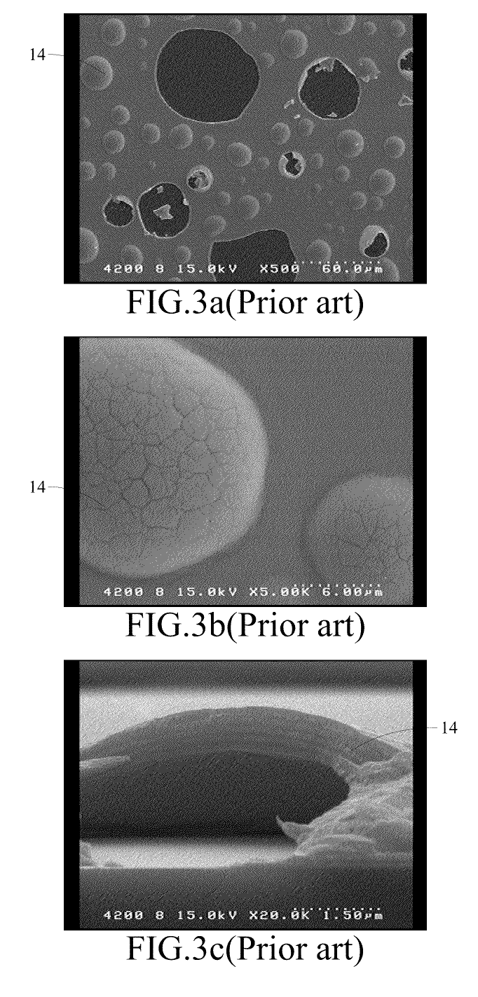

### DETAILED DESCRIPTION OF THE INVENTION

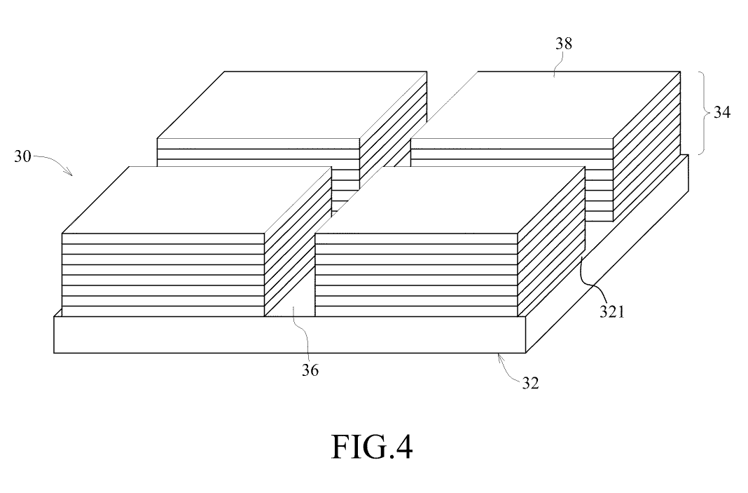

FIG. 4 is a diagram illustrating a high-temperature-durable optical film structure in accordance with an example of the present invention. As illustrated in FIG. 4, the high-temperature-durable optical film structure 30 comprises a transparent substrate 32 having an upper surface 321, and an optical layer structure formed on the upper surface 321. In the present example, the optical layer structure is a multi-layer thin film structure 34 including, but not limited to, two different materials. In other examples, the optical layer structure may also include one or more materials. The multi-layer thin film structure 34 has a plurality of passage structures 36, which pass through the multi-layer thin film structure 34, and the multi-layer thin film structure 34 is divided into a plurality of optical blocks 38.

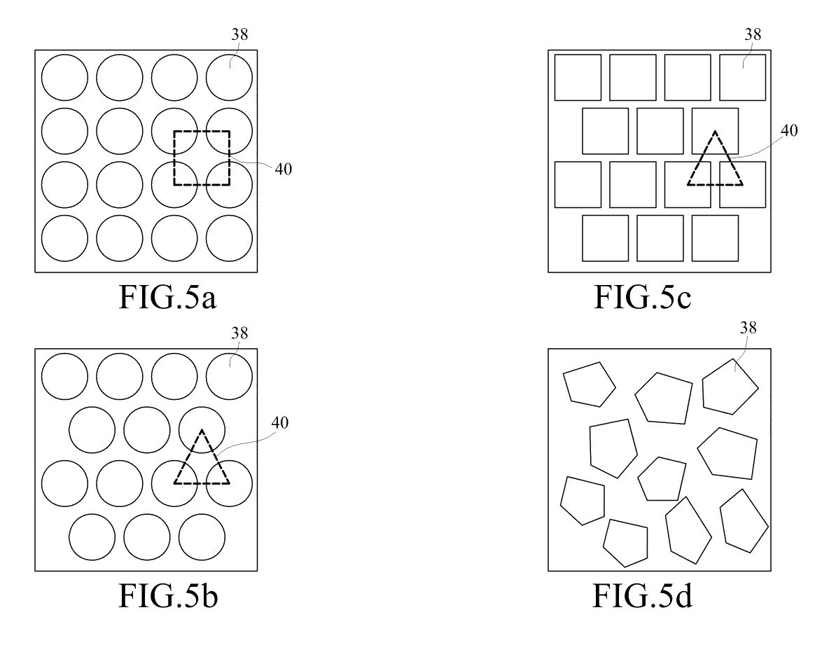

In the present example embodiment, the passage structures 36 comprise crossed passages. In the present example embodiment, the shape of the optical blocks 38 is square and may be arranged in square configuration. In other example embodiments, the shape of the optical blocks 38 may be triangular, circular or polygonal shape, or any other shape, and may be arranged in triangle, hexagon or polygon configuration. FIG. 5a to FIG. 5d are diagrams respectively illustrating the shape and the distribution of different optical blocks in the present invention. As illustrated in FIG. 5a, the shape of the optical blocks 38 is circular shape and are arranged in square configuration (illustrated by dotted line in figure). As illustrated in FIG. 5b, the shape of the optical blocks 38 is circular shape and are arranged in triangle configuration (illustrated by dotted line in figure). As illustrated in FIG. 5c, the shape of the optical blocks 38 is square shape and are arranged in triangle configuration (illustrated by dotted line in figure). As illustrated in FIG. 5d, the shape of the optical blocks 38 is irregular shape and are randomly arranged.

Furthermore, the material of the multi-layer thin film structure 34 may include Ta₂O₅, TiO₂, Nb₂O₅, Al₂O₃, SiO₂ or MgF, or their combinations. The use waveband of the multi-layer thin film structure 34 comprises X-ray, far-ultraviolet (EUV), ultraviolet, visible light, infrared, near-infrared or far-infrared. Further, the widths of the passage structures 36 may be proportional to the area of every optical block 38. In the present example embodiment, when the materials of the multi-layer thin film structure 34 and the transparent substrate 32 are the same, the widths of the passage structures 36 are directly proportion to the tolerance temperature of the optical film structure 30. In the present example embodiment, the width of the passage structures 36 is larger than or equal to 0.01 μm.

In the present invention, when the multi-layer thin film structure 34 is expanded due to the high process temperature, the passage structures 36 can be used as a space for releasing the thermal stress and thereby reduce the possibility of the film 38 from deforming and peeling. Furthermore, a following high-temperature-durable optical thin film device may be fabricated without any deformation and peeling.

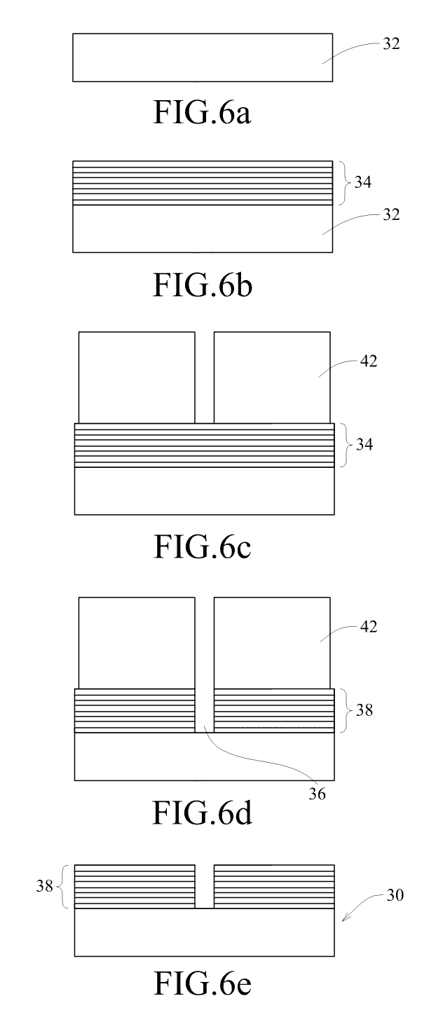

FIG. 6a to FIG. 6e illustrates a flow of a method for fabricating a high-temperature-durable optical film structure in accordance with an example embodiment of the present invention. First, as illustrated in FIG. 6a, a transparent substrate 32 is provided. Next, as illustrated in FIG. 6b, a multi-layer thin film structure 34 is formed over the transparent substrate 32 by, for example, a sputtering, evaporation, chemical vapor deposition, chemical liquid phase deposition, chemical vapor phase epitaxy or chemical liquid phase epitaxy process. Next, portions of the multi-layer thin film structure 34 are removed by performing, for example, a physical etching process or a chemical etching process. In the present example, a photo etching process may be performed to remove portions of the multi-layer thin film structure 34. As illustrated in FIG. 6c, a plurality of protruded stop layers 42 are formed over the multi-layer thin film structure 34, wherein the protruded stop layers 42 are periodically arranged. Next, as illustrated in FIG. 6d, the multi-layer thin film structure 34 is etched using the protruded stop layers 42 as masks to form the plurality of optical blocks 38 and the plurality of passage structures 36. Finally, as shown in FIG. 6e, the protruded stop layers 42 are removed to obtain the high-temperature-durable optical film structure 30.

Wherein, the protruded stop layers 42 are formed by photolithography, nano imprint lithography or microcontact printing process. The multi-layer thin film structure 34 is etched by performing a plasma etching process, and the plasma source comprises direct current, alternate current, radio frequency, microwave or ion bombardment.

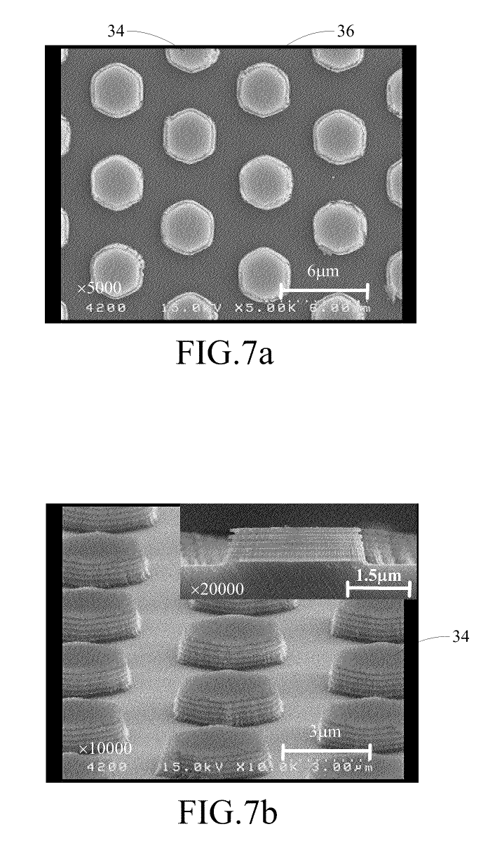

FIG. 7a and FIG. 7b are respectively a SEM vertical view and a SEM lateral view illustrating the high-temperature-durable optical film structure before baking. As illustrated in the figures, the multi-layer thin film structure 34 comprises a plurality of passage structures 36.

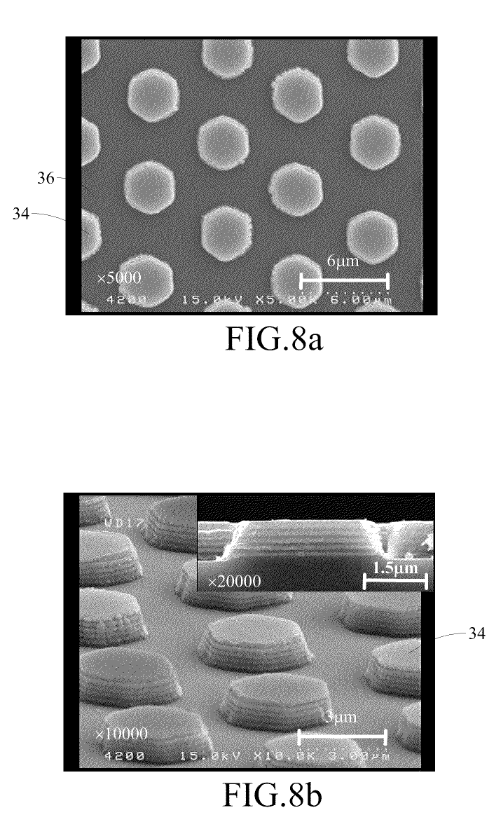

FIG. 8a and FIG. 8b are respectively a SEM vertical view and a SEM lateral view illustrating the high-temperature-durable optical film structure after baking to 1200° C. As illustrated in FIG. 8a and FIG. 8b, the high temperature treatment does not deform and peel off the multi-layer thin film structure 34.

To sum up, the optical film structure of the present invention may sustain the high temperature fabrication processes, and an optical thin film device formed from the optical film structure may be effectively operated in a high temperature operating condition. For example, when the optical film structure is applied to a filter of a solar cell, the filter may sustain the temperature as high as 1000 degree celsius, which may be attained by focusing the solar intensity one thousand times on one square centimeter area. Therefore, the solar collector and the solar filter of the solar cell may be operated for a long duration of time without using any additional heat sink. Additionally, the optical film structure can also be applied to an optical filter of a mini-projector to replace the traditional optical filter so as to gain the advantages of the filter and enduring high temperature. Furthermore, the optical film structure may also be fabricated on an epitaxy growth substrate to serve as a high-temperature-durable high reflection mirror, and then a LED luminescent material is epitaxially grown on the high reflection mirror. Therefore, the high reflection mirror may be used to achieve multiple internal reflection of light from the back of the LED to increase the efficiency of luminance.

While the invention is susceptible to various modifications and alternative forms, a specific example thereof has been shown in the drawings and is herein described in detail. It should be understood, however, that the invention is not to be limited to the particular form disclosed, but to the contrary, the invention is to cover all modifications, equivalents, and alternatives falling within the spirit and scope of the appended claims.

What is claimed is:

1. A high-temperature-durable optical film structure comprising:
a substrate; and
an optical layer structure formed on a surface of said substrate, wherein said optical layer structure comprises a plurality of passage structures to divide said optical layer structure into a plurality of optical blocks.

2. The high-temperature-durable optical film structure according to claim 1, wherein said passage structures cross each other.

3. The high-temperature-durable optical film structure according to claim 1, wherein said optical layer structure comprise a multi-layer thin film structure.

4. The high-temperature-durable optical film structure according to claim 1, wherein said optical blocks has a triangular, circular, square or polygonal shape.

5. The high-temperature-durable optical film structure according to claim 1, wherein said optical blocks are arranged in square, triangle, hexagon or polygon configuration.

6. The high-temperature-durable optical film structure according to claim 1, wherein a width of said passage structures is larger than or equal to 0.01 μm.

7. The high-temperature-durable optical film structure according to claim 1, wherein said optical layer structure comprise Ta₂O₅, TiO₂, Nb₂O₅, Al₂O₃, SiO₂, MgF or any combination thereof.

8. The high-temperature-durable optical film structure according to claim 1, wherein said optical layer structure are suitable for X-ray, far-ultraviolet, ultraviolet, visible light, infrared, near-infrared or far-infrared light.

9. The high-temperature-durable optical film structure according to claim 1, wherein said substrate comprises a transparent substrate.

10. A fabricating method of a high-temperature-durable optical film structure comprising:
providing a substrate;
forming an optical layer structure over a surface of said substrate; and
forming a plurality of passage structures on said optical layer structure.

11. The fabricating method of the high-temperature-durable optical film structure according to claim 10, wherein the step of forming said optical layer structure is implemented by a sputtering, an evaporation, a chemical vapor deposition, a chemical liquid phase deposition, a chemical vapor phase epitaxy or a chemical liquid phase epitaxy process.

12. The fabricating method of the high-temperature-durable optical film structure according to claim 10, wherein the step of forming said passage structures is implemented by removing a portion of said optical layer structure.

13. The fabricating method of the high-temperature-durable optical film structure according to claim 12, wherein the step of removing said portion of said optical layer structure is implemented by performing a physical etching process or a chemical etching process.

14. The fabricating method of the high-temperature-durable optical film structure according to claim 12, wherein the step of removing said portion of said optical layer structure is implemented by a photo etching process comprising:
forming a plurality of protruded stop layers over said optical layer structure;
etching said optical layer structure using said protruded stop layers as masks to form said passage structures on said optical layer structure by etching said portion of said optical layer structure; and
removing said protruded stop layers.

15. The fabricating method of the high-temperature-durable optical film structure according to claim 14, wherein the step of forming said protruded stop layers is implemented by performing a photolithography, a nano imprint lithography or a microcontact printing process.

16. The fabricating method of the high-temperature-durable optical film structure according to claim 14, wherein said protruded stop layers are periodically arranged.
